(19) United States
(12) Patent Application Publication
(10) Pub. No.: US 2023/0217828 A1
(43) Pub. Date: Jul. 6, 2023

(54) ACTUATOR

(71) Applicant: Panasonic Intellectual Property Management Co., Ltd., Osaka (JP)

(72) Inventor: KAZUKI KOMAKI, Osaka (JP)

(21) Appl. No.: 18/181,609

(22) Filed: Mar. 10, 2023

Related U.S. Application Data
(63) Continuation of application No. PCT/JP2021/031641, filed on Aug. 30, 2021.

(30) Foreign Application Priority Data
Oct. 30, 2020 (JP) 2020-182016

(51) Int. Cl. H10N 30/20; H10N 30/80

(52) U.S. Cl. CPC H10N 30/20; H10N 30/802

(57) ABSTRACT

Provided is an actuator including a piezoelectric element capable of satisfying three of a large amplitude, a high resonance frequency, and a large generated force. Actuator (100) is a drive source having a cantilever structure in which one end is a fixed end and the other end is displaced, and includes first piezoelectric body (110), second piezoelectric body (120), and shim member base (130) disposed between first piezoelectric body (110) and second piezoelectric body (120). In first piezoelectric body (110) and second piezoelectric body (120), piezoelectric body removal parts (110a) and (120a) are formed.

### BACKGROUND

### 1. Technical Field

The present disclosure relates to an actuator including a piezoelectric body.

### 2. Description of the Related Art

An actuator including a piezoelectric body applies an electric field to the piezoelectric body to cause the piezoelectric body to expand and contract and generate a driving force. In the actuator having a unimorph structure, a plate that does not expand and contract in an expansion and contraction direction of the piezoelectric body is jointed to one surface of the piezoelectric body, and expansion and contraction of the piezoelectric body with respect to the plate is converted into warpage of the plate. The actuator having a bimorph structure joints two piezoelectric bodies and warps the entire piezoelectric bodies by extension of one of them and contraction of the other of them.

The actuator described in PTL 1 is an actuator having the unimorph structure, and has a cantilever structure with a fixed base end, so that displacement of a tip end due to warpage is used to change an angle of a mirror.

### CITATION LIST

### Patent Literature

PTL 1: WO 2013/114857 A

### SUMMARY

However, in general, due to the nature of the piezoelectric body, in an actuator including the piezoelectric body, a displacement amount and a resonance frequency are in a trade-off relationship, and it has been difficult to achieve an actuator that satisfies a large displacement amount and a high resonance frequency. The present disclosure has been made in view of the above problems, and an object of the present disclosure is to provide an actuator capable of satisfying a large displacement amount and a high resonance frequency.

In order to achieve the above object, an actuator according to one aspect of the present disclosure includes a first drive body, a second drive body, and a shim material. The first drive body includes a first piezoelectric body extending in a first axial direction intersecting a polarization axis. The second drive body includes a second piezoelectric body extending in the first axial direction. The shim material is disposed between the first drive body and the second drive body. One end of the actuator in the first axial direction is a fixed end, and the other end in the first axial direction is a free end. In the actuator, the shim material is exposed from the first piezoelectric body and the second piezoelectric body at the end in the first axial direction.

According to the actuator of the present disclosure, a large displacement amount and a high resonance frequency can be obtained.

### BRIEF DESCRIPTION OF THE DRAWINGS

FIG. 1 is a perspective view illustrating an actuator of a first exemplary embodiment;

FIG. 2 is a side view illustrating the actuator of the first exemplary embodiment;

FIG. 3A is a perspective view illustrating an actuator of another exemplary embodiment;

FIG. 3B is a perspective view illustrating an actuator of another exemplary embodiment; and

FIG. 3C is a perspective view illustrating an actuator of another exemplary embodiment.

### DETAILED DESCRIPTIONS

Exemplary embodiments of an actuator according to the present disclosure will be described below with reference to the drawings. Numerical values, shapes, materials, constituent elements, positional relationships and connection states of constituent elements, steps, orders of steps, and the like described in the following exemplary embodiments are merely examples, and are not intended to limit the present disclosure. In the following, a plurality of inventions may be described in one exemplary embodiment, but constituent elements not described in claims are described as optional constituent elements regarding the invention according to the claims. The drawings are schematic views in which emphasis, omission, and ratio adjustment are appropriately performed in order to describe the present disclosure, and may be different from actual shapes, positional relationships, and ratios.

### First Exemplary Embodiment

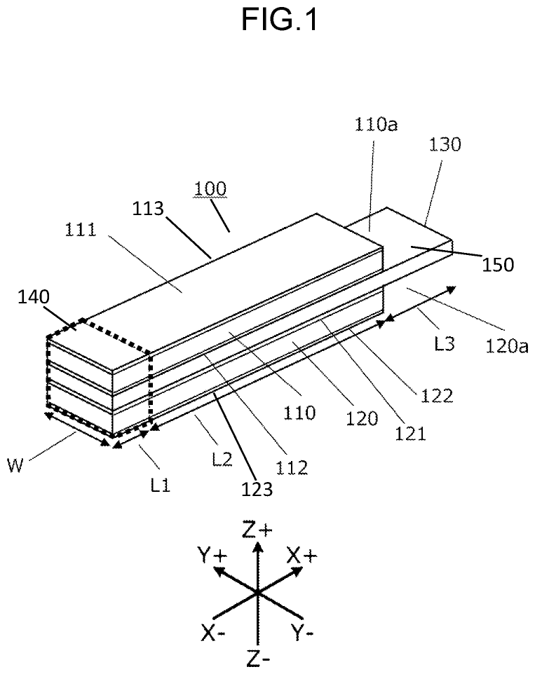

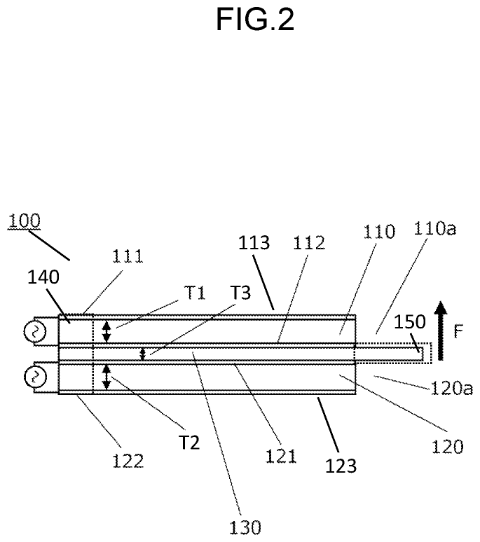

FIG. 1 is a perspective view illustrating actuator 100 according to the first exemplary embodiment. FIG. 2 is a side view illustrating actuator 100 according to the first exemplary embodiment. Actuator 100 is a drive source of a cantilever structure in which one end is fixed to form fixed end 140 (a fixing structure is not illustrated) and the other end is displaced to form free end 150. Actuator 100 includes first piezoelectric body 110, second piezoelectric body 120, and shim material 130 disposed between first piezoelectric body 110 and second piezoelectric body 120. In FIGS. 1 and 2, fixed end 140 and free end 150 are each indicated by a region surrounded by a broken line.

First piezoelectric body 110 is a member that expands and contracts in the other end direction with respect to one end fixed by application of an electric field, and includes first electrode 111 and second electrode 112 on an upper surface and a back surface, respectively. That is, first piezoelectric body 110, first electrode 111, and second electrode 112 constitute first drive body 113.

Second piezoelectric body 120 is a member that expands and contracts in the other end direction with respect to one end fixed by application of an electric field, and includes third electrode 121 and fourth electrode 122 on an upper surface and a back surface, respectively. That is, second piezoelectric body 120, third electrode 121, and fourth electrode 122 constitute second drive body 123. Actuator 100 has a configuration in which shim material 130 is held between first drive body 113 and second drive body 123.

First piezoelectric body 110 is what is called a piezoelectric element whose polarization is aligned in a direction (Z-axial direction in the drawing) in which first electrode 111 and second electrode 112 are arranged. The shape of first piezoelectric body 110 is illustrated as a rectangular parallelepiped shape, but is not limited to this as long as a cantilever structure in which one end is fixed at fixed end 140 and the other end is displaced is formed. Here, the rectangular parallelepiped shape includes a rectangular parallelepiped, and also includes a shape partially having a protrusion, a cutout, a round, an inclination, or the like as long as the shape looks a rectangular parallelepiped as a whole. First piezoelectric body 110 extends in the first axial direction (X-axial direction in the drawing) intersecting the polarization axis (Z-axis in the drawing).

Here, first electrode 111 and second electrode 112 are electrodes for applying an electric field to first piezoelectric body 110. First electrode 111 is disposed on one end surface side (upper surface) of first piezoelectric body 110 in the polarization direction, and second electrode 112 is disposed on the other end surface side (back surface) of first piezoelectric body 110 in the polarization direction. First electrode 111 and second electrode 112 have a rectangular sheet shape substantially identical to the shape of the surface having the maximum area of first piezoelectric body 110. Substantially identical includes identical, and also includes a shape partially including a cutout, a hole, a round, and the like as long as the shape looks identical to the shape of the surface as a whole.

Second piezoelectric body 120 is what is called a piezoelectric element whose polarization is aligned in a direction (Z-axial direction in the drawing) in which third electrode 121 and fourth electrode 122 are arranged. The shape of second piezoelectric body 120 is illustrated as a rectangular parallelepiped shape, but is not limited to this as long as a cantilever structure in which one end is fixed at fixed end 140 and the other end is displaced is formed. Here, the rectangular parallelepiped shape includes a rectangular parallelepiped, and also includes a shape partially having a protrusion, a cutout, a round, an inclination, or the like as long as the shape looks a rectangular parallelepiped as a whole. Second piezoelectric body 120 extends in the first axial direction (X-axial direction in the drawing) intersecting the polarization axis (Z-axis in the drawing).

Furthermore, third electrode 121 and fourth electrode 122 are electrodes for applying an electric field to second piezoelectric body 120. Third electrode 121 is disposed on one end surface side (upper surface) of second piezoelectric body 120 in the polarization direction, and fourth electrode 122 is disposed on the other end surface side (back surface) of second piezoelectric body 120 in the polarization direction. Third electrode 121 and fourth electrode 122 have a rectangular sheet shape substantially identical to the shape of the surface having the maximum area of second piezoelectric body 120. Substantially identical includes identical, and also includes a shape partially including a cutout, a hole, a round, and the like as long as the shape looks identical to the shape of the surface as a whole.

Here, as described above, shim material 130 is disposed between first piezoelectric body 110 and second piezoelectric body 120. A material of shim material 130 is not particularly limited, but is a steel material such as copper, titanium, chromium, or tungsten, a compound thereof, silicon, or ceramics or a resin made of an oxide or a nitride.

A forming method of actuator 100 is not particularly limited. The forming method varies depending on the size and application of actuator 100 and the required actuator performance. For example, actuator 100 may be formed by separately manufacturing each component and then jointing these components. Actuator 100 may be formed using a technique of manufacturing micro electro mechanical systems (MEMS).

In FIG. 2, T1 is a thickness of first piezoelectric body 110, T2 is a thickness of second piezoelectric body 120, and T3 is a thickness of shim material 130. In FIG. 1, L1 is a length of a restraint part (corresponding to a part fixing one end of actuator 100, that is, a length of fixed end 140). L2 is a length of a piezoelectric drive part, that is, a length of movable parts of first piezoelectric body 110 and second piezoelectric body 120. L3 is a length (length of an exposed part) in which first piezoelectric body 110 and second piezoelectric body 120 are not disposed and shim material 130 is exposed. A region immediately above shim material 130 where first piezoelectric body 110 is not disposed is called first exposed part 110a. A region immediately below shim material 130 where second piezoelectric body 120 is not disposed is called second exposed part 120a. First exposed part 110a and second exposed part 120a are disposed in regions opposite to each other as viewed from shim material 130. As an example, first exposed part 110a and second exposed part 120a are respectively formed by removing a part of first piezoelectric body 110 and a part of second piezoelectric body 120 formed on shim material 130. That is, first exposed part 110a and second exposed part 120a correspond to the lengths of a part (piezoelectric body removal part) where the part of first piezoelectric body 110 and the part of second piezoelectric body 120 are removed. W is a width of first piezoelectric body 110, second piezoelectric body 120, and shim material 130. In this exemplary embodiment, these three widths are identical, but these widths need not necessarily be completely identical.

The above description has described that first exposed part 110a and second exposed part 120a are formed by removing the part of first piezoelectric body 110 and the part of second piezoelectric body 120. However, instead of removing the part of first piezoelectric body 110 and the part of second piezoelectric body 120, first exposed part 110a and second exposed part 120a may be formed as follows. That is, first drive body 113 including first piezoelectric body 110 and second drive body 123 including second piezoelectric body 120 may be made shorter than shim material 130 in the first axial direction, and may be jointed so that free end 150 of shim material 130 is exposed to form first exposed part 110a and second exposed part 120a.

When an electric field is applied via first electrode 111 and second electrode 112 such that first piezoelectric body 110 contracts, and an electric field is applied via third electrode 121 and fourth electrode 122 such that second piezoelectric body 120 extends, actuator 100 is displaced in the direction of arrow F in FIG. 2.

In the following table, the actuator of the first exemplary embodiment is compared with a comparative actuator (Comparative example in the table), and the displacement amount and the resonance frequency in the table are values obtained by simulation.

TABLE 1

| | Com- | First |
|---|---|---|
| | parative | exemplary |
| | example | embodiment |
| W (width of first piezoelectric body, second | 12.0 mm | 12.0 mm |
| piezoelectric body, and shim material) | | |
| T1 (Thickness of first piezoelectric body) | 0.3 mm | 0.3 mm |
| T2 (Thickness of second piezoelectric body) | 0.3 mm | 0.3 mm |
| T3 (Thickness of shim material) | 0.1 mm | 0.1 mm |
| L1 (Length of restraint part) | 5.0 mm | 5.0 mm |
| L2 (Length of piezoelectric drive part) | 26.0 mm | 21.0 mm |
| L3 (Length of exposed part) | 0.0 mm | 5.0 mm |
| Displacement amount | 128 μm | 122 μm |
| Resonance frequency | 525 Hz | 725 Hz |

In Table 1, the actuator of the comparative example is a general cantilever actuator in which length L3 of the piezoelectric body removal part is 0 mm (that is, the piezoelectric body is not removed).

As shown in this table, in the actuator of the first exemplary embodiment, the displacement amount is almost the same as that of the actuator of the comparative example, but the resonance frequency is higher than that of the actuator of the comparative example. Thus, the actuator of the first exemplary embodiment satisfies the requirement of a large displacement amount and a high resonance frequency.

In a piezoelectric actuator represented by a cantilever shape, the displacement amount and the resonance frequency are in a trade-off relationship. It is effective to increase the actuator length in order to improve the displacement amount of the actuator, but on the other hand, extension of the actuator length reduces the resonance frequency and the generated force at the free end part, which is the tip end.

There is a similar contradictory relationship with respect to change in the actuator width and the thickness, and it has been difficult to improve all the performance of the actuator in design of the shape of an actuator that is unambiguous such as the length, the width, and the thickness.

Here, the mass reduction at the tip end of the actuator is effective for improving the resonance frequency. The piezoelectric body at the tip end is removed to reduce the tip end mass, and the length to the exposed shim plate tip end is sufficiently secured while the piezoelectric body having a certain length from the fixed portion is secured for securing displacement, thereby making it possible to suppress a decrease in the displacement amount of the tip end even when compared with an actuator having the piezoelectric body up to the tip end.

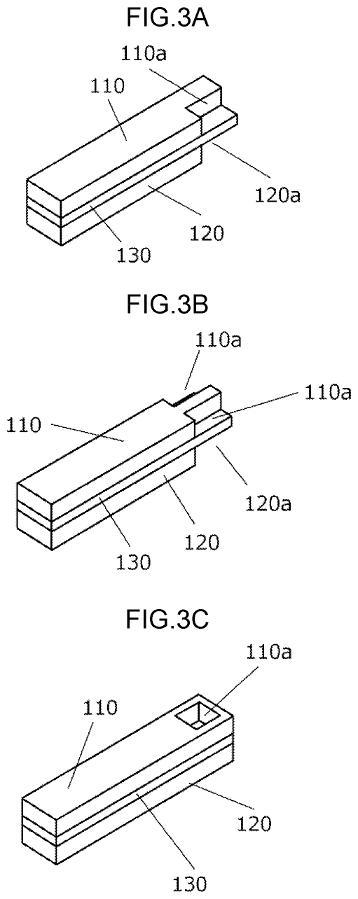

FIGS. 3A to 3C illustrate actuators according to other exemplary embodiments.

In the configuration of FIG. 3A, first exposed part 110a and second exposed part 120a are not formed on the entire other end, but are formed only on one side surface.

In the structure of FIG. 3A, even if the piezoelectric body at the tip end is not completely removed, even a partially removed structure can reduce the tip end mass, and can further suppress a decrease in the displacement amount.

In the configuration of FIG. 3B, first exposed part 110a and second exposed part 120a are formed on both side surfaces of the other end, and the piezoelectric body remains in the central part.

As compared with the structure of FIG. 3A, the configuration of FIG. 3B maintains symmetry in the actuator width direction, and stably amplitudes in the z-axial direction (see FIG. 1 for the axis).

Furthermore, in the configuration of FIG. 3C, first exposed part 110a is formed only in the central part of the other end. Although not visible in the drawing, second exposed part 120a is also formed at the central part of second piezoelectric body 120 similarly to first exposed part 110a.

Similarly to the configuration of FIG. 3B, as compared with the structure of FIG. 3A, the configuration of FIG. 3C maintains symmetry in the actuator width direction, and stably amplitudes in the z-axial direction (see FIG. 1 for the axis).

The present disclosure is not limited to the above exemplary embodiments. For example, another exemplary embodiment implemented by optionally combining the constituent elements described in the present description or by excluding some of the constituent elements may be an exemplary embodiment of the present disclosure.

The present disclosure also includes variations obtained by making various modifications conceivable by those skilled in the art without departing from the spirit of the present disclosure, in other words, without departing from the meaning indicated by the wording described in the claims.

The present disclosure can be used for various applications such as a device operated by a small actuator and a projector device that displays an image by reflecting laser light.

What is claimed is:

1. An actuator comprising:
a first drive body including a first piezoelectric body extending in a first axial direction intersecting a polarization axis;
a second drive body including a second piezoelectric body extending in the first axial direction; and
a shim material disposed between the first drive body and the second drive body,
wherein
one end of the actuator in the first axial direction is a fixed end, and another end of the actuator in the first axial direction is a free end, and
the shim material is exposed from the first piezoelectric body and the second piezoelectric body at an end in the first axial direction.

2. The actuator according to claim 1, wherein the end of the shim material which is exposed from the first piezoelectric body and the second piezoelectric body in a part of the free end of the actuator.

3. The actuator according to claim 2, wherein the shim material is exposed from the first piezoelectric body and the second piezoelectric body on one side surface of the actuator.

4. The actuator according to claim 2, wherein the shim material is exposed from the first piezoelectric body and the second piezoelectric body on both side surfaces of the actuator.

5. The actuator according to claim 2, wherein the shim material is further exposed from the first piezoelectric body and the second piezoelectric body at a central part of the actuator.

6. The actuator according to claim 1, wherein the first piezoelectric body and the second piezoelectric body are removed to expose the shim material.
